(19) United States
(12) Patent Application Publication
(10) Pub. No.: US 2015/0243429 A1
(43) Pub. Date: Aug. 27, 2015

(54) MAGNETIC MODULE AND CASING THEREOF

(71) Applicant: DELTA ELECTRONICS, INC., Taoyuan Hsien (TW)

(72) Inventors: CHENG-EN LIAO, Taoyuan Hsien (TW); YI-LIN CHEN, Taoyuan Hsien (TW); HSI-CHEN LIU, Taoyuan Hsien (TW)

(21) Appl. No.: 14/483,467

(22) Filed: Sep. 11, 2014

(30) Foreign Application Priority Data
Feb. 27, 2014 (CN) 201410068791.1

(51) Int. Cl. H01F 27/04; H01F 27/29; H03H 7/01; H01F 27/02

(52) U.S. Cl. CPC H01F 27/04; H01F 27/027; H01F 27/292; H03H 7/01

(57) ABSTRACT

A magnetic module includes a magnetic element and a casing. The magnetic element includes a bobbin, a magnetic core assembly, a plurality of first pins and a plurality of second pins. A winding coil assembly is wound around the bobbin. The magnetic core assembly is partially embedded within the bobbin. The first pins are connected with at least one first outlet part of the winding coil assembly. The second pins are connected with at least one second outlet part of the winding coil assembly. The casing may cover the magnetic element. When the magnetic element is covered by the casing, the first pins and the second pins are exposed outside the casing. The casing is made of a composite material containing a ceramic material and a metallic material.

### TECHNICAL FIELD

The present disclosure relates to a magnetic module, and more particularly to a magnetic module for use in a high temperature process of a reflow furnace.

### BACKGROUND OF THE DISCLOSURE

A surface mount technology (SMT) is a method for mounting electronic components on a surface of a circuit board. The surface mount technology is capable of automatically fabricating small-sized, reliable, high-density and cost-effective electronic products. For mounting the electronic components on the printed circuit board, the circuit board and the electronic components are heated in a reflow furnace to melt the solder paste, so that the pins of the electronic components are covered by molten solder paste. After the circuit board and the electronic components are cooled, the molten solder paste is solidified. Consequently, the electronic components are securely welded on the circuit board.

Generally, the operating temperature of the reflow furnace has to be higher than the melting point of the solder paste. For example, the operating temperature of the reflow furnace may be as high as 180° C. The high temperature process may cause damage of the electronic component, the winding coil or the insulation tape. For preventing from damage of the winding coil or the insulation tape, the coil and the tape used in the conventional transformer should withstand high temperature. In other words, the product price is very high.

Therefore, there is a need of providing an improved product in order to avoid the above drawbacks.

### SUMMARY OF THE DISCLOSURE

An object of present disclosure provides a magnetic module for preventing from damage of high temperature on the winding coil or the insulation tape.

Another object of present disclosure provides a magnetic module with low fabricating cost.

A further object of present disclosure provides a magnetic module with reduced electro-magnetic interference (EMI).

In accordance with an aspect of the present disclosure, there is provided a magnetic module. The magnetic module includes a magnetic element and a casing. The magnetic element includes a bobbin, a magnetic core assembly, a plurality of first pins and a plurality of second pins. A winding coil assembly is wound around the bobbin. The magnetic core assembly is partially embedded within the bobbin. The first pins are connected with at least one first outlet part of the winding coil assembly. The second pins are connected with at least one second outlet part of the winding coil assembly. The casing is configured to cover the magnetic element. When the magnetic element is covered by the casing, the first pins and the second pins are exposed outside the casing. The casing is made of a composite material containing a ceramic material and a metallic material.

In an embodiment, the magnetic element is a transformer, an inductor or an electronic filter.

In an embodiment, the magnetic element is a surface mount device (SMD).

In an embodiment, each of the first pins and the second pins has a weld part.

In an embodiment, the bobbin includes a channel, wherein the magnetic core assembly is partially embedded within the channel.

In an embodiment, the casing includes an accommodation space, a first recess, and a second recess. A winding part of the bobbin and the magnetic core assembly are accommodated within the accommodation space. A first pin seat of the bobbin is accommodated within the first recess. A second pin seat of the bobbin is accommodated within the second recess.

In an embodiment, the metallic material is selected from a transition metal or an alloy of at least two transition metals.

In an embodiment, the transition metal is selected from iron, cobalt, nickel, tungsten or molybdenum.

In an embodiment, the bobbin includes a plurality of protrusion posts, and the casing includes a plurality of indentations corresponding to the protrusion posts. The protrusion posts are engaged with the corresponding indentations, so that the casing is fixed on the bobbin.

In accordance with another aspect of the present disclosure, there is provided a casing for covering a magnetic element. When the magnetic element is covered by the casing, a plurality of first pins and a plurality of second pins of the magnetic element are exposed outside the casing. The casing is made of a composite material containing a ceramic material and a metallic material.

The above contents of the present disclosure will become more readily apparent to those ordinarily skilled in the art after reviewing the following detailed description and accompanying drawings, in which:

### BRIEF DESCRIPTION OF THE DRAWINGS

FIG. 1 is a schematic perspective view illustrating a magnetic module according to an embodiment of the present disclosure;

FIG. 2 is a schematic exploded view illustrating the magnetic module according to the embodiment of the present disclosure and taken along a first viewpoint;

FIG. 3 is a schematic exploded view illustrating the magnetic module according to the embodiment of the present disclosure and taken along a second viewpoint; and

FIG. 4 is a schematic exploded view illustrating the magnetic element of the magnetic module according to the embodiment of the present disclosure.

### DETAILED DESCRIPTION OF THE PREFERRED EMBODIMENT

The present disclosure will now be described more specifically with reference to the following embodiments. It is to be noted that the following descriptions of preferred embodiments of this disclosure are presented herein for purpose of illustration and description only. It is not intended to be exhaustive or to be limited to the precise form disclosed.

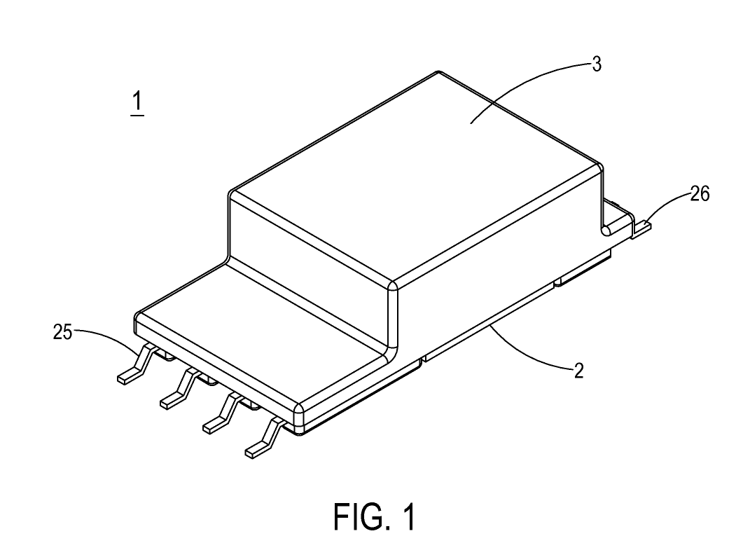

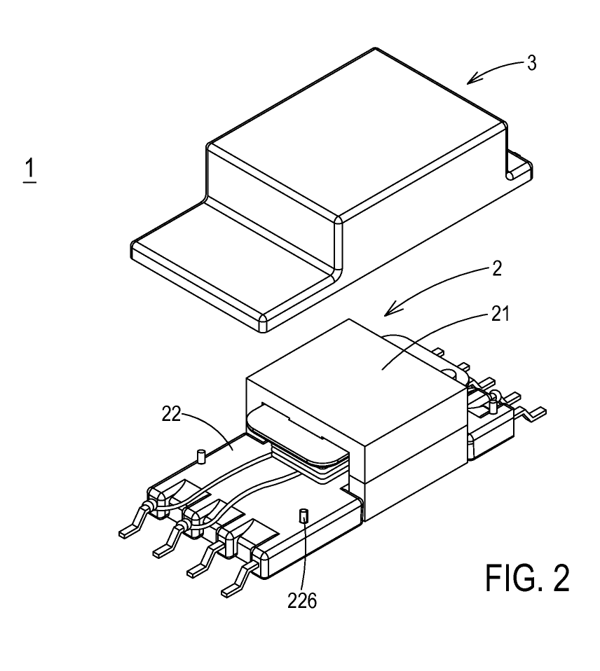

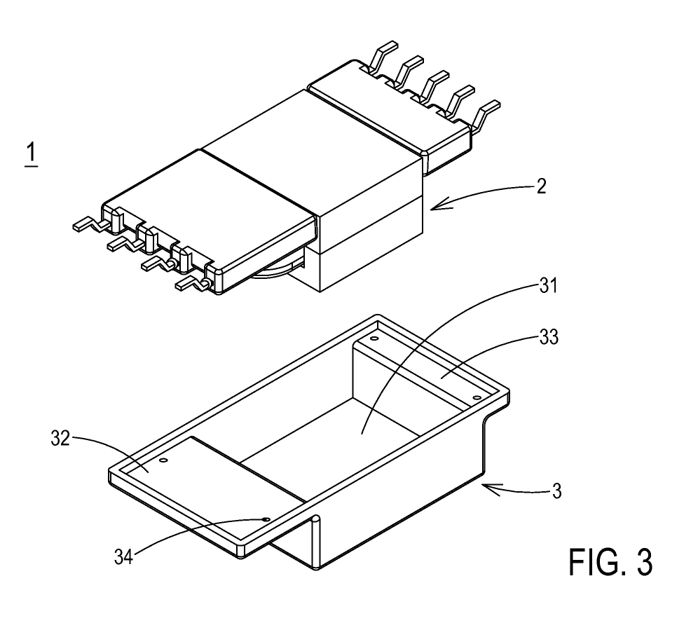

FIG. 1 is a schematic perspective view illustrating a magnetic module according to an embodiment of the present disclosure. FIG. 2 is a schematic exploded view illustrating the magnetic module according to the embodiment of the present disclosure and taken along a first viewpoint. FIG. 3 is a schematic exploded view illustrating the magnetic module according to the embodiment of the present disclosure and taken along a second viewpoint. As shown in FIGS. 1-3, the magnetic module 1 includes a magnetic element 2 and a casing 3. The casing 3 is placed over the magnetic element 2 in order to cover magnetic element 2. After the majority of the magnetic element 2 is covered by the casing 3, the pins 25 and 26 of the magnetic element 2 are exposed outside the casing 3. In this embodiment, the magnetic element 2 is a transformer. Alternatively, in some other embodiments, the magnetic element 2 is an inductor or an electronic filter.

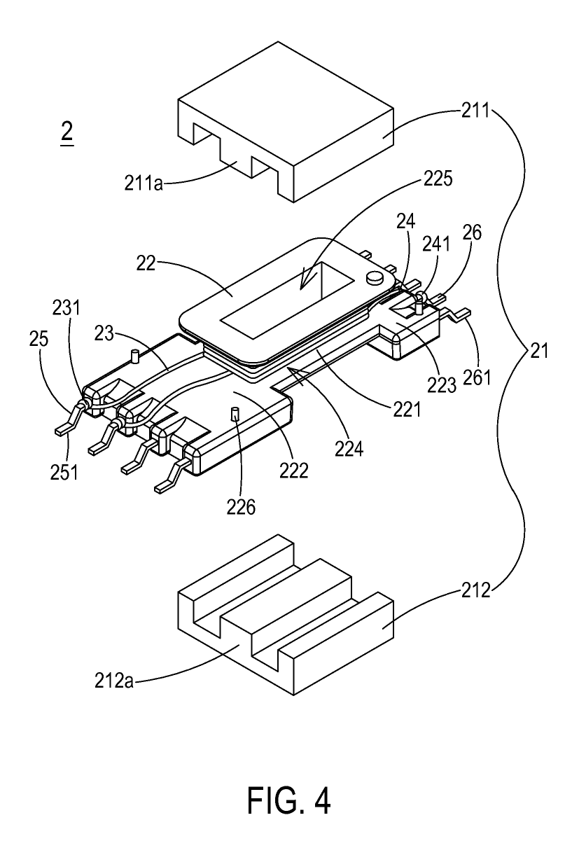

FIG. 4 is a schematic exploded view illustrating the magnetic element of the magnetic module according to the embodiment of the present disclosure. As shown in FIG. 4, the magnetic element 2 includes a magnetic core assembly 21, a bobbin 22, a winding coil assembly, a plurality of first pins 25, and a plurality of second pins 26. In this embodiment, the winding coil assembly includes a primary winding coil 23 and a secondary winding coil 24. The locations of the primary winding coil 23 and the secondary winding coil 24 are not restricted. The bobbin 22 includes a winding part 221, a first pin seat 222, and a second pin seat 223. The first pin seat 222 and the second pin seat 223 are extended from two opposite sides of the winding part 221. The first pins 25 are disposed on the first pin seat 222. The second pins 26 are disposed on the second pin seat 223. The primary winding coil 23 and the secondary winding coil 24 are overlapped with each other and wound around the winding part 221 of the bobbin 22. Moreover, the primary winding coil 23 and the secondary winding coil 24 are isolated and separated from each other through insulation tapes (not shown). The outlet parts 231 of the primary winding coil 23 are connected with the corresponding first pins 25. The outlet parts 241 of the secondary winding coil 24 are connected with the corresponding second pins 26.

The magnetic core assembly 21 includes a first magnetic core 211 and a second magnetic core 212. The first magnetic core 211 has a first middle portion 211a, and the second magnetic core 212 has a second middle portion 212a. The first middle portion 211a of the first magnetic core 211 and the second middle portion 212a of the second magnetic core 212 are embedded into a channel 225 of the bobbin 22. Consequently, the primary winding coil 23 and the secondary winding coil 24 interact with the magnetic core assembly 21 to achieve the purpose of voltage regulation.

For largely reducing the volume of the product, the magnetic element 2 is a surface mount device (SMD). That is, the magnetic element 2 is mounted on a circuit board (not shown) by a surface mount technology (SMT). Each of the first pins 25 has a weld part 251, and each of the second pins 26 has a weld part 261. For mounting the magnetic element 2 on the circuit board, solder paste is coated on bonding pads of the circuit board corresponding to the weld parts 251 and 261 and in contact with the weld parts 251 and 261. After the magnetic element 2 is covered by the casing 3 and the magnetic module 1 is assembled, the magnetic module 1 and the circuit board are heated in a reflow furnace. Consequently, the solder paste is molten, and the weld parts 251 and 261 of the pins 25 and 26 are covered by molten solder paste. After the circuit board and the magnetic module 1 are cooled, the molten solder paste is solidified. Consequently, the magnetic module 1 securely welded on the circuit board.

As previously described, the operating temperature of the reflow furnace has to be higher than the melting point of the solder paste. The high temperature process may cause damage of the magnetic element 2, the winding coil or the insulation tape. In accordance with a feature of the present disclosure, the casing 3 of the magnetic module 1 is effective to solve the above drawbacks. As shown in FIG. 3, the casing 3 includes an accommodation space 31, a first recess 32, and a second recess 33. The accommodation space 31 is used for accommodating the winding part 221 of the bobbin 22 and the magnetic core assembly 21. The first recess 32 and the second recess 33 are used for accommodating the first pin seat 222 and the second pin seat 223 of the bobbin 22, respectively.

Please refer to FIG. 1 again. After the magnetic element 2 is covered by the casing 3, the pins 25 and 26 of the magnetic element 2 and a bottom surface of the magnetic element 2 are exposed outside the casing 3. That is, the majority of the magnetic element 2 is sheltered by the casing 3. Under this circumstance, the magnetic module 1 is assembled. After the magnetic module 1 is assembled, the subsequent welding process may be performed. In accordance with the present disclosure, the casing 3 is made of the material that withstands high temperature. Consequently, the casing 3 may be used as a protective cover for reducing the influence of the heat on the magnetic element 2. Since the casing 3 is capable of reducing the influence of the heat on the magnetic element 2 during the high temperature process in the reflow furnace, the possibility of causing damage of the winding coil or the insulation tape will be minimized. Moreover, since the casing 3 is used as the protective cover of the magnetic element 2, the winding coil and the insulation tape may be made of the material that withstands low temperature. Under this circumstance, the fabricating cost of the magnetic element is reduced.

In an embodiment, the casing 3 is made of a ceramic material. Since the ceramic material can withstand high temperature, the heat-insulating efficacy of the casing 3 is increased.

In another embodiment, the casing 3 is made of a metallic material. Consequently, the casing 3 has a function of reducing electro-magnetic interference (EMI). For example, the casing 3 is an iron cover, but is not limited thereto.

In a preferred embodiment, the casing 3 is made of a composite material including a ceramic material and a metallic material. Consequently, the casing 3 has the functions of increasing the heat-insulating efficacy and reducing the electro-magnetic interference (EMI). Preferably, the metallic material is a transition metal or an alloy of at least two transition metals. An example of the transition metal includes but is not limited to iron, cobalt, nickel, tungsten or molybdenum.

Please refer to FIGS. 2 and 3 again. The casing 3 and the bobbin 22 have engaging structures. For example, the bobbin 22 includes a plurality of protrusion posts 226, and the casing includes a plurality of indentations 34 corresponding to the protrusion posts 226. When the magnetic element 2 is covered by the casing 3, the protrusion posts 226 of the bobbin 22 are engaged with the corresponding indentations 34 of the casing 3. Consequently, the casing 3 is fixed on the bobbin 22. It is noted that the locations of the protrusion posts and the indentations may be exchanged. Moreover, the examples of the engaging structures are not restricted to the protrusion posts and the indentations. That is, any other engaging structures for fixing the casing 3 on the bobbin 22 may be applied to the magnetic module 1 of the present disclosure.

From the above descriptions, the present disclosure provides a magnetic module. The magnetic module includes a magnetic element and a casing. The magnetic element is covered by the casing. After the magnetic element is covered by the casing, the pins of the magnetic element are exposed outside the casing. That is, the majority of the magnetic element is sheltered by the casing. After the magnetic module is assembled, the subsequent welding process may be performed. Since the casing is made of the material that withstands high temperature, the casing may be used as a protective cover for reducing the influence of the heat on the magnetic element. During the high temperature process in the reflow furnace, the possibility of causing damage of the winding coil or the insulation tape will be minimized. Moreover, since the casing is used as the protective cover of the magnetic element, the winding coil and the insulation tape may be made of the material that withstands low temperature. Under this circumstance, the fabricating cost of the magnetic element is reduced. In case that the casing is made of a composite material including a ceramic material and a metallic material, the casing has the functions of increasing the heat-insulating efficacy and reducing the electro-magnetic interference (EMI). In comparison with the conventional technology, the magnetic module of the present disclosure is more advantageous.

While the disclosure has been described in terms of what is presently considered to be the most practical and preferred embodiments, it is to be understood that the disclosure needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A magnetic module, comprising:
a magnetic element comprising a bobbin, a magnetic core assembly, a plurality of first pins and a plurality of second pins, wherein a winding coil assembly is wound around the bobbin, the magnetic core assembly is partially embedded within the bobbin, the first pins are connected with at least one first outlet part of the winding coil assembly, and the second pins are connected with at least one second outlet part of the winding coil assembly; and
a casing configured for covering the magnetic element, wherein when the magnetic element is covered by the casing, the first pins and the second pins are exposed outside the casing, wherein the casing is made of a composite material containing a ceramic material and a metallic material.

2. The magnetic module according to claim 1, wherein the magnetic element is a transformer, an inductor or an electronic filter.

3. The magnetic module according to claim 1, wherein the magnetic element is a surface mount device (SMD).

4. The magnetic module according to claim 1, wherein each of the first pins and the second pins has a weld part.

5. The magnetic module according to claim 1, wherein the bobbin comprises a channel, wherein the magnetic core assembly is partially embedded within the channel.

6. The magnetic module according to claim 1, wherein the casing comprises an accommodation space, a first recess and a second recess, and the bobbin comprises a first pin seat and a second pin seat, wherein the accommodation space is configured for accommodating a winding part of the bobbin and the magnetic core assembly, the first recess is configured for accommodating the first pin seat of the bobbin, and the second recess is configured for accommodating the second pin seat of the bobbin.

7. The magnetic module according to claim 1, wherein the metallic material is selected from a transition metal or an alloy of at least two transition metals.

8. The magnetic module according to claim 7, wherein the transition metal is selected from iron, cobalt, nickel, tungsten or molybdenum.

9. The magnetic module according to claim 1, wherein the bobbin comprises a plurality of protrusion posts, and the casing comprises a plurality of indentations corresponding to the protrusion posts, wherein the protrusion posts are engaged with the corresponding indentations, so that the casing is fixed on the bobbin.

10. The magnetic module according to claim 1, wherein the bobbin comprises a plurality of first engaging structures, and the casing comprises a plurality of second engaging structures corresponding to the first engaging structures, wherein the first engaging structures are engaged with the corresponding second engaging structures, so that the casing is fixed on the bobbin.

11. A casing for covering a magnetic element, wherein when the magnetic element is covered by the casing, a plurality of first pins and a plurality of second pins of the magnetic element are exposed outside the casing, wherein the casing is made of a composite material containing a ceramic material and a metallic material.
